(19) United States
(12) Patent Application Publication
(10) Pub. No.: US 2013/0257464 A1
(43) Pub. Date: Oct. 3, 2013

(54) BATTERY SYSTEM

(71) Applicant: Hideyasu Takatsuji, Tokyo (JP)

(72) Inventor: Hideyasu Takatsuji, Tokyo (JP)

(73) Assignee: MITSUBISHI HEAVY INDUSTRIES, LTD., Tokyo (JP)

(21) Appl. No.: 13/988,807

(22) PCT Filed: Dec. 8, 2011
(86) PCT No.: PCT/JP2011/078417

§ 371 Date: May 22, 2013

(30) Foreign Application Priority Data
Dec. 9, 2010 (JP) 2010-274382

(51) Int. Cl. G01R 27/02

(52) U.S. Cl. CPC G01R 27/02
USPC 324/705

(57) ABSTRACT

A battery system includes: a first battery cell; a second battery cell; a power load supplied with current from the first battery cell and the second battery cell; a connection which electrically connects a negative electrode terminal of the first battery cell and a positive electrode terminal of the second battery cell; a connection which electrically connects the first negative electrode terminal and the second positive electrode terminal; a cell balancing circuit which causes electromotive voltages of the first battery cell and the second battery cell to be substantially equal; and a controller, wherein the controller enables the current to be supplied to the power load after causing the electromotive voltages of the first battery cell and the second battery cell to be substantially equal, thereby determining looseness of the connection.

### TECHNICAL FIELD

The present invention relates to a battery system, and more particularly, to a battery system which determines a connection state between battery cells of a battery pack.

Priority is claimed on Japanese Patent Application No. 2010-274382, filed Dec. 9, 2010, the content of which is incorporated herein by reference.

### BACKGROUND ART

Battery cells used in a battery system are generally used in a form of a battery pack. That is, mostly, a plurality of battery cells are connected in series or in parallel using a connection as a power supply line to be used as a battery pack. The physical connection between the connection and an electrode terminal of the battery cell is made by using a screw or the like. The battery pack supplies power to, for example, a power load provided in the battery system.

However, when the physical connection is loosened, the power supply to the power load is interrupted. In addition, in a case where the looseness further progresses and the connection is finally removed from the battery cell, the power supply to the power load is cut off. This means that, in a case where the battery system is an electric vehicle, rapid deceleration occurs and there is concern that an accident may occur.

Here, various techniques of detecting the connection state of the battery pack, that is, looseness of the physical connection, have been reported (refer to PTLs 1 and 2).

### CITATION LIST

### Patent Literature

[PTL 1] Japanese Unexamined Patent Application, First Publication No. 2008-241421
[PTL 2] Japanese Unexamined Patent Application, First Publication No. 2009-257928

### SUMMARY OF INVENTION

### Technical Problem

However, in the technique of PTL 1, since a special sensor which detects the looseness of the physical connection is used, there are concerns for the battery system being complex and the cost thereof being increased.

In addition, in the technique of PTL 2, the removing the connection from the battery cell can be detected, but a case where the connection is not removed from the battery cells yet despite the physical connection being loosened cannot be detected.

Here, an object of the present invention is to provide a battery system capable of minutely determining a connection state between battery cells constituting a battery pack with a simple configuration, and specifically, a battery system capable of detecting a case where a physical connection is loosened despite a connection being not removed from the battery cell, without the use of the special sensor.

### Solution to Problem

A battery system of the present invention includes: a first battery cell including a first positive electrode terminal and a first negative electrode terminal; a second battery cell including a second positive electrode terminal and a second negative electrode terminal; a power load which is disposed between the first positive electrode terminal and the second negative electrode terminal and is supplied with current from the first battery cell and the second battery cell; a connection which electrically connects the first negative electrode terminal and the second positive electrode terminal; a first voltage sensor for measuring a cell voltage of the first battery cell via the connection; a second voltage sensor for measuring a cell voltage of the second battery cell via the connection; a cell balancing circuit which enables electromotive voltages of the first battery cell to be substantially equal to that of the second battery cell; and a controller. The controller supplies the irrent to the power load while controlling the electromotive voltages of the first battery cell to be substantially equal to that of the second battery cell by using the first and the second voltage the cell balancing circuit, thereby determining looseness of the connection.

That is, the contact resistances of the connection and the electrode terminals are configured to be included in an electrical path where the first and the second voltage sensors perform measurement, and furthermore, current supply to the power load is performed after causing the electromotive voltages of the first battery cell and the second battery cell to be substantially equal by using the cell balancing circuit. Therefore, it is possible to easily detect the looseness state of the connection by the difference between the voltages measured by the first and second voltage sensors.

### Advantageous Effects of Invention

According to the battery system of the present invention, the connection state of each of the battery cells constituting the battery pack can be minutely determined with a simple configuration.

### BRIEF DESCRIPTION OF DRAWINGS

FIG. 1 is a schematic diagram of a battery system of an embodiment of the present invention.

FIG. 2 is a schematic diagram illustrating a physical connection relationship between battery cells and connections in the battery system of the embodiment of the present invention.

FIG. 3 is a schematic circuit diagram illustrating an electrical connection relationship between the battery cells and the connections in the battery system of the embodiment of the present invention.

FIG. 4 is an explanatory diagram for explaining control of a controller used in the battery system of the embodiment of the present invention.

### DESCRIPTION OF EMBODIMENTS

A battery system according to an embodiment of the present invention, as one of features, arranges a voltage sensor that measures a cell voltage to cause an electrical path on which the cell voltage of a battery cell is measured to include a contact resistance of a connection member as a power supply line and an electrode terminal, determines a state of electrical connection between the connection member and each battery cell at the time of starting up the battery system, and performs appropriate control and processing. Hereinafter, the battery system will be described in detail with reference to the drawings.

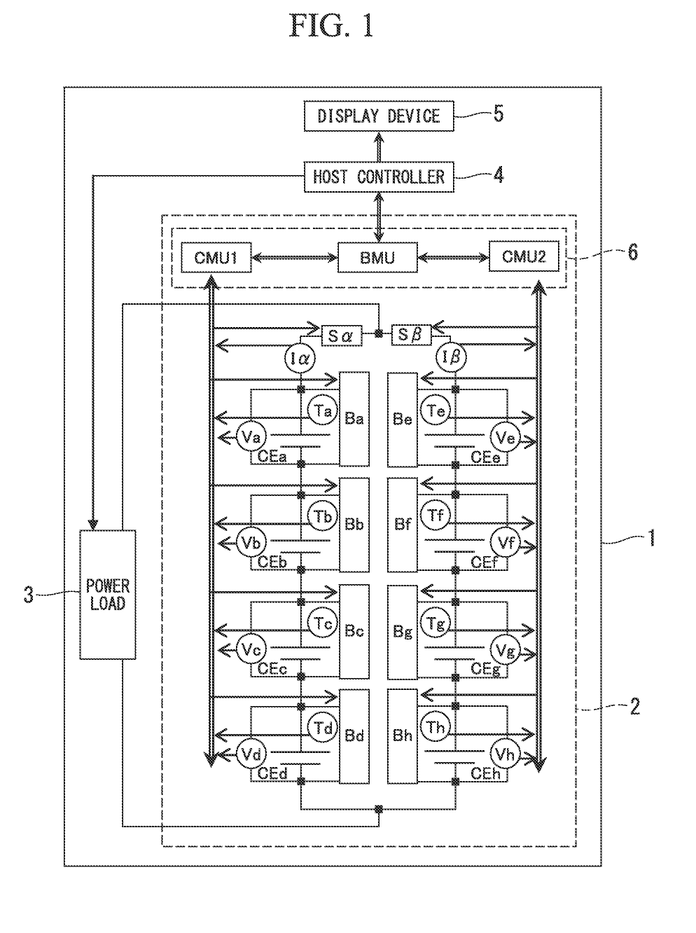

Hereinafter, the battery system according to the embodiment of the present invention will be described with reference to the drawings. FIG. 1 is a diagram illustrating the configuration of the battery system 1. The battery cell used in the battery system 1 can use any battery of a primary battery, a secondary battery, and the like depending on the use of the battery system 1. However, as an example of the battery cell, a chargeable and dischargeable battery cell, for example, a battery cell of a lithium ion secondary battery which is a storage battery is used for the description.

The battery system 1 includes a battery module 2, a power load 3, a host controller 4, and a display device 5.

The battery module 2 including a battery pack constituted by a plurality of battery cells CEa to CEh and a BMS (Battery Management System) 6 that is a monitoring controller of the battery pack is fitted to the inside of the battery system 1 from the outside of the battery system 1 to be fixed. The battery module 2 is modular and thus can be easily exchanged from the outside of the battery system 1. In addition, the power load 3, the host controller 4, and the display device 5 are assembled to the battery system 1 in advance. Also, here, there are cases where the host controller 4 and the BMS 6 are collectively referred to as simply a controller.

Here, for example, the battery system 1 may be a moving body such as an industrial vehicle such as a forklift, a train in which a wheel is connected to an electric motor that is the power load 3, or a moving body such as an electric vehicle, or a moving body such as an airplane or a ship in which a propeller or a screw is connected to an electric motor that is the power load 3. In addition, for example, the battery system 1 may be a power storage system for family use or a stationary system such as a system interconnection facilitating power storage system combined with natural energy power generation using a windmill, sunlight, or the like. That is, the battery system 1 may a system using at least discharging of power of the plurality of battery cells that constitute, the battery pack, and may also be a system using charging and discharging.

The battery pack in the battery module 2 supplies power to the power load 3 of the battery system 1, and a first arm constituted by the battery cells CEa to CEd connected in series and a second arm constituted by the battery cells CEe to CEh connected in series are connected in parallel. In addition, hereinafter, the configurations of a voltage sensor V, a temperature sensor T, a cell balancing circuit B, and the like corresponding to each of the battery cells CEa to CEh are appropriately provided with a to h at the ends of the reference numerals of the corresponding configurations to clarify which of the battery cells corresponds to the description of the configurations.

In the plurality of battery cells CEa to CEh constituting the battery pack, the temperature sensors Ta to Th for measuring cell temperatures and the voltage sensors Va to Vh for measuring cell voltages are arranged to correspond to the respective battery cells one by one. In addition, in the respective battery cells, the cell balancing circuits Ba to Bh each of which electrically connects a positive electrode terminal and a negative electrode terminal of the corresponding battery cell for discharging to cause the battery cell to have a predetermined voltage are arranged to correspond to the respective battery cells one by one.

In addition, a single current sensor corresponding to each arm is disposed. Here, a current sensor Iα for the first arm and a current sensor Iβ for the second arm are disposed to measure current flowing through each arm. In addition, in each arm, a single arm switch for causing the corresponding arm to be electrically connected or not connected to the power load 3 is disposed. Here, an arm switch Sa for the first arm and an arm switch Sβ for the second arm are disposed.

Measurement information which is measured and output by various sensors that measure the cell temperatures, the cell voltages, and the current flowing through each of the arms described above is input to the BMS 6 described later.

In addition, here, a single arm is formed by connecting the four battery cells in series, and a total of two anus are configured to be connected in parallel. However, the number of battery cells connected to each of the arms and the number of arms can be designed to be one or more.

The BMS 6 is configured to include two CMUs (Cell Monitor Units), that is, a CMU1 and a CMU2, and a BMU (Battery Management Unit).

Here, the CMU1 and the CMU2 include ADCs (Analog Digital Converters) (not illustrated), receive a plurality of pieces of measurement information detected and output by the various sensors as analog signals, and convert the analog signals into corresponding digital signals by the ADCs so as to be output to the BMU as a plurality of parameters for calculating and the like associated information (which is the information associated with the measurement information and includes a charging rate (SOC) of each of the battery cells calculated by the BMU). In addition, according to this embodiment, as illustrated in FIG. 1, each CMU is connected with the various sensors by buses or signal lines.

The host controller 4 controls the power load 3 according to a user's instruction (for example, in a case where the battery system 1 is an electric vehicle, the amount of an accelerator pedal pressed by a user), receives the associated information of the battery pack transmitted from the BMS 6, and controls the display device 5 to appropriately display the associated information on the display device 5. In addition, in a case where the associated information is determined as an abnormal value, the host controller 4 turns on an abnormality lamp built in the display device 5 or the like, and sounds alarm by operating an acoustic device such as a buzzer built in the display device 5 to stimulate the senses of sight and hearing with light and sound and attract user's attention.

The display device 5 is, for example, a monitor such as a liquid crystal panel including the acoustic device, and can perform displaying or the like of the associated information of the plurality of battery cells CEa to CEh constituting the battery pack based on the control from the host controller 4.

The power load 3 is, for example, a power converter such as an electric motor or an inverter connected to a wheel of the electric vehicle. The power load 3 may also be an electric motor that drives a wiper or the like.

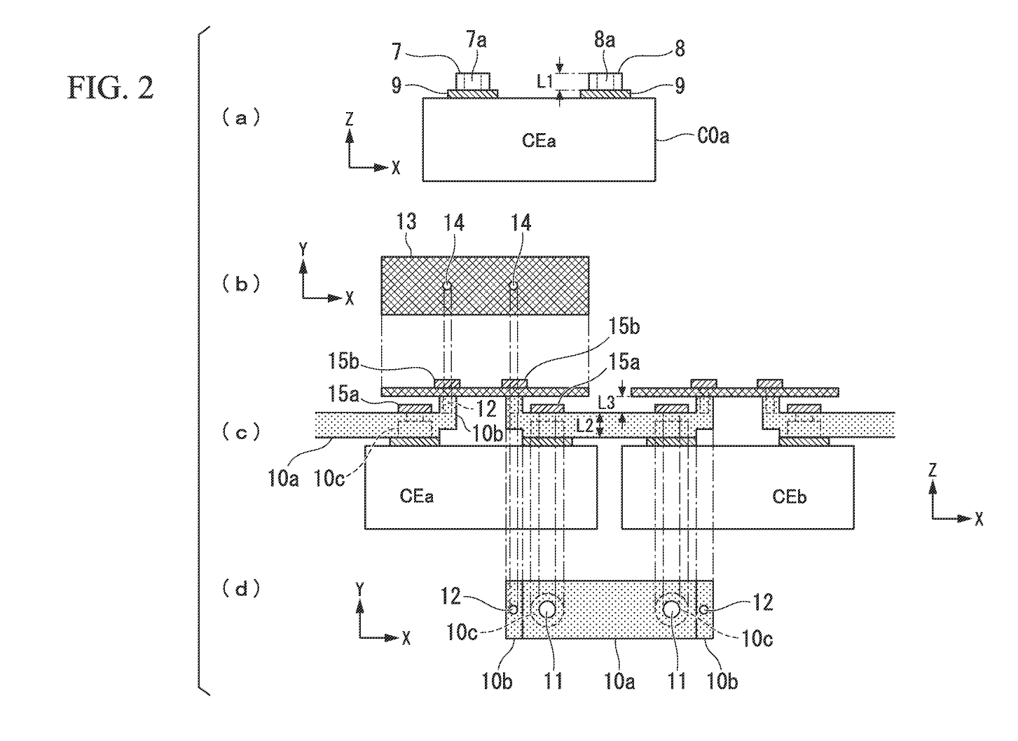

In the battery system 1, configurations and operations for “connection looseness determination” of each of the battery cells and the control thereof described later will be described in detail using FIGS. 2 to 4. From the viewpoint of easy understanding, a single arm here, the first arm having the battery cells CEa to CEd connected in series will described with focus thereon. The following description is the same as that of the other arm, and description of the other arm is omitted.

First, using FIG. 2, the physical connection relationship between the battery cell and the connection member, which is the premise of the “connection looseness determination”, will be described. All FIGS. 2(a) to 2(d) will be described by using the same Cartesian coordinate system.

FIG. 2(a) is a diagram illustrating a schematic configuration of a single battery cell (here, the battery cell CEa is representatively illustrated). The battery cell CEa includes a rectangular battery container C0a and a positive electrode terminal 7 and a negative electrode terminal 8 which have cylindrical shapes and are fixed to the battery container C0a in a state of protruding from the battery container C0a.

Protruding heights of the electrode terminals (the positive electrode terminal 7 and the negative electrode terminal 8) are lengths L1 in the Z direction. In addition, a female screw 7a is formed in the positive electrode terminal 7 as a concave portion in the Z direction, and a female screw 8a is formed in the negative electrode terminal 8 as the concave portion in the Z direction.

A positive electrode plate (coated with a positive electrode active material such as lithium manganese oxide) stored in the battery container C0a is electrically connected to the positive electrode terminal 7, and a negative electrode plate (coated with a negative electrode active material such as carbon) stored in the battery container C0a is electrically connected to the negative electrode terminal 8. In addition, an electrolyte or an electrolytic solution (also referred to as an electrolytic solution or the like) is stored in the battery container C0a to allow the battery container C0a to function as a battery by the positive electrode plate, the negative electrode plate, and the electrolytic solution or the like.

The battery container C0a, may be made of a metal or a plastic resin, and in a case of being made of a conductive material, insulating resins 9 are disposed between the battery container C0a and the electrode terminals to electrically insulate the electrode terminals (the positive electrode terminal 7 and the negative electrode terminal 8) from the battery container C0a.

The other battery cells CEb to CEh have the same configuration.

The plurality of battery cells illustrated in FIG. 2(a) is prepared to be electrically connected in series with connections made of a metal. Specifically, as illustrated in the side view of FIG. 2(c) to diagram viewed from the XZ plane), the battery cell CEa and the battery cell CEb are electrically connected in series with a busbar 10. Hereinafter, using FIG. 2(d) which is a top view of the busbar 10 (a diagram viewed from the XY plane) and FIG. 2(c) mentioned above, the configuration of the busbar 10 and the connection of the two battery cells with the busbar 10 will be described. In addition, between FIGS. 2(c) and 2(d), dot-dashed lines corresponding to the positional relationship therebetween are drawn.

The busbar 10 is a plate-like connection made of a metal having conductivity. The busbar 10 includes a flat plate-like flat plate portion 10a and two protruding portions 10h which are connected to the flat plate portion 10a and are disposed with the flat plate portion 10a interposed therebetween. The protruding portion 10b protrudes in the Z direction by a length L3 from the surface on the +Z side between the two surfaces on the XY plane of the flat plate portion 10a. That is, a cross-sectional shape on the X7 plane is an approximately U shape. It is desirable that the flat plate portion 10a and the protruding portion 10b be integrally formed by deforming the same material with a die and mold.

The thickness of the flat plate portion 10a in the Z direction) is a length L2, and is designed to be greater than the length L1 of the height of the electrode terminals. That is, L2>L1. In addition, in the flat plate portion 10a, two concave portions 10c in which the above-mentioned protruding portions of the electrode terminals can be fitted in and which have substantially the similar shapes and slightly smaller shapes than the protruding portions are formed. With the slightly smaller configuration, the busbar 10 can sufficiently come into contact with the concave portions 10c of the electrode terminals and the electrode terminals can be fixed to the busbar 10. Typically, one of the two concave portions 10c is fitted in the positive electrode terminal of a certain battery cell and the other thereof is fitted in the negative electrode terminal of another battery cell.

In addition, in the flat plate portion 10a, through-holes 11 which are through-holes that penetrate the flat plate portion 10a from the concave portions 10c in the Z direction and have a shape smaller than the cross-sectional shape of the concave portion 10c on the XY plane are formed. After the concave portion 10c is fitted in the electrode terminal to cause the electrode terminal to come into contact with the busbar 10, a shaft portion of a male screw 15a is inserted and screwed into the through-hole 11, and the busbar 10 and the battery cell are firmly fixed to each other while pressing the flat plate portion 10a of the busbar 10 with a head portion of the male screw 15a. In addition, threads corresponding to the female screw 7a and the female screw 8a are formed on the male screw 15a. In addition, a length of the head portion of the male screw 15a in the Z direction is smaller than the length L3.

In the protruding portion 10b of the busbar 10, treaded holes 12 (female screw) for fixing a circuit board 13 to the busbar 10 are formed in the Z direction. As illustrated in the top view of FIG. 2(b) (a diagram viewed from the XV plane), a circuit board 13 has two through-holes 14 formed (in addition, between FIGS. 2(b) and 2(c), dot-dashed lines corresponding to the positional relationship therebetween are drawn). Between the two through-holes 14, a shaft portion of a male screw 15b is inserted into one through-hole 14 and screwed into the threaded hole 12 of a certain busbar 10, and the busbar 10 and the circuit board 13 are firmly fixed to each other by pressing the circuit board 13 with a head portion of the male screw 15b. In addition, between the two through-holes 14, a shaft portion of a male screw 15b is inserted into the other through-hole 14 and screwed into the threaded hole 12 of another busbar 10, and the busbar 10 and the circuit board 13 are firmly fixed to each other by pressing the circuit board 13 with a head portion of the male screw 15b.

The circuit board 13 is a circuit board which is electrically connected between the positive electrode terminal and the negative electrode terminal of the single battery cell, and is suspended and fixed onto the two busbars 10 as described above. In addition, threads corresponding to the threaded hole 12 (female screw) are formed on the male screw 15b.

The circuit board 13 not only has the voltage sensor and the cell balancing circuit fixed thereto, which corresponds to the single battery cell, but also is suspended and fixed as described above. Therefore, printed wiring in which the voltage sensor and the cell balancing circuit are automatically and electrically connected to the positive electrode terminal and the negative electrode terminal of the battery cell via the protruding portions 10b of the two busbars 10 is formed. The temperature sensor corresponding to the battery cell may be fixed to the circuit board 13.

Although not illustrated, a bus or a signal line connected to the BMS 6 is connected to the circuit board 13.

As described above, the busbar 10 is fitted to the electrode terminals by surrounding the electrode terminals, and thus can obtain a sufficient contact area to the electrode terminals and is further configured to have a sufficient cross-sectional area in the ZY direction reducing an effect heat generation even in a case where high current flows.

In addition, without current flowing through the flat plate portion 10a between the two through-holes 11 of the busbar 10 which is a path of the current flowing to the power load 3, an electrical path between the voltage sensor and the electrode terminals of the battery cell measured by the voltage sensor is formed in the protruding portion 10b, and thus a voltage can be measured more accurately.

Moreover, the circuit board 13 not only includes the various sensors and the cell balancing circuit provided in the corresponding single battery cell, but also has the predetermined wiring formed therein as the printed wiring in advance. Therefore, the various sensors and the cell balancing circuit can be connected to the predetermined battery cell at a time, and accordingly, an efficiency of manufacturing the battery system can be enhanced.

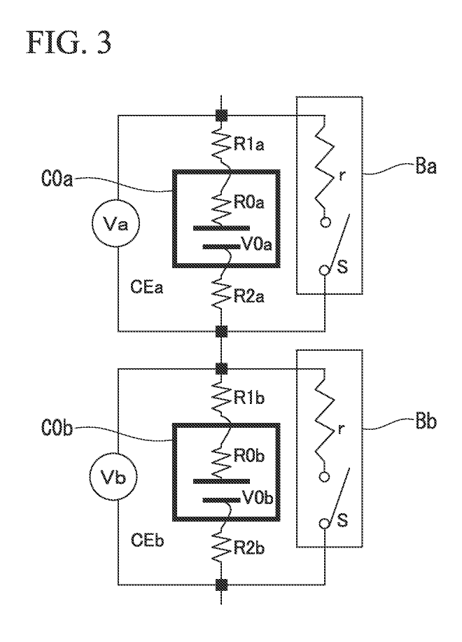

In FIG. 3, the configuration of FIG. 2 is illustrated as an electric circuit. In the battery container C0a of the battery cell CEa, a battery having an electromotive voltage V0a and an internal resistance R0a are connected in series. In addition, the voltage sensor Va and the cell balancing circuit Ba disposed in the circuit board 13 are electrically connected to the protruding portion 10b of the busbar 10, and thus are connected to the battery having the electromotive voltage V0a and the internal resistance R0a via a contact resistance R1a generated when the battery cell CEa and a certain busbar 10 come into contact with each other on the positive electrode terminal side and a contact resistance R2a generated when the battery cell CEa and the other busbar 10 come into contact with each other on the negative electrode terminal side.

That is, the one end of the internal resistance R0a is connected to the positive electrode of the battery having the electromotive voltage V0a, the one end of the contact resistance R1a is connected to the other end of the internal resistance R0a, the positive electrode terminal of the voltage sensor Va and the positive electrode terminal of the cell balancing circuit Ba are connected to the other end of the contact resistance R1a, the negative electrode terminal of the voltage sensor Va and the negative electrode terminal of the cell balancing circuit Ba are connected to the one end of the contact resistance R2a, and the negative electrode of the battery having the electromotive voltage V0a is connected to the other end of the contact resistance R2a.

In addition, in a battery container C0b of the battery cell CEb, a battery having an electromotive voltage V0b and an internal resistance R0b are connected in series. In addition, the voltage sensor Vb and the cell balancing circuit Bb disposed in the circuit board 13 are electrically connected to the protruding portion 10b of the busbar 10, and thus are connected to the battery having the electromotive voltage V0b and the internal resistance R0b via a contact resistance R1b generated when the battery cell CEb and the busbar 10 come into contact with each other on the positive electrode terminal side and a contact resistance R2b generated when the battery cell CEb and the busbar 10 come into contact with each other on the negative electrode terminal side. The case of the battery cell CEa described above is the same.

That is, in the configuration, the one end of the internal resistance R0b is connected to the positive electrode of the battery having the electromotive voltage V0b, the one end of the contact resistance R1b is connected to the other end of the internal resistance R0b, the positive electrode terminal of the voltage sensor Vb and the positive electrode terminal of the cell balancing circuit Bb are connected to the other end of the contact resistance R1b, the negative electrode terminal of the voltage sensor Vb and the negative electrode terminal of the cell balancing circuit Bb are connected to the one end of the contact resistance R2b, and the negative electrode of the battery having t electromotive voltage V0b is connected to the other end of the contact resistance R2b.

In addition, since the battery cell CEa and the battery cell CEb are connected by the same busbar 10, the other end of the contact resistance R1b is connected to the one end of the contact resistance R2a.

All the cell balancing circuits B have the same configuration, and are constituted by a switch S configured as a transistor or the like and a resistance r connected to the switch. Here, both the cell balancing circuits Ba and Bb have a configuration in which the positive electrode terminal thereof is connected to the one end of the resistance r, the negative electrode terminal thereof is connected to the switch S, and the other end of the resistance r is electrically connected to the negative electrode terminal when the switch S is “closed”. In addition, opening and closing of the switch S is controlled by the BMS 6.

Here, the “connection looseness determination” process of each of the battery cells CEa to CEh will be described using FIG. 3. The “connection looseness determination” is to detect and determine a connection state corresponding to the looseness of the busbar 10 which is a connection member (power supply line) connecting the electrode terminals of each of the battery cells of the battery pack, that is a state of electrical connection between the power supply line and the electrode terminal of the battery cell. Therefore, the “connection looseness” means that the contact resistance of the electrode terminal of the battery cell and the power supply line that conies into contact with the electrode terminal is increased higher than an initial contact resistance when the power supply line is firmly fixed to the electrode terminal by a screw or the like.

Specifically, the “connection looseness determination” process is to detect and determine increases in the contact resistance R1 (the contact resistance R1a or R1b in FIG. 3) or the contact resistance R2 (the contact resistance R2a or R2b in FIG. 3) from a predetermined resistance value to perform an appropriate process in the controller.

In addition, in the battery cells CEa to CEh, although the internal resistances R0a to R0h vary in a certain range due to the degree of deterioration of the battery cells, in a case where the increase in the contact resistance R1 or R2 is detected, the variation in the certain range is minute and is thus negligible. Therefore, hereinafter, the internal resistance RD is temporarily described to be a constant.

In the battery system 1 of this embodiment, the controller, specifically, the host controller 4 performs the “connection looseness determination” at the time of starting up the battery system 1. This will be described sequentially.

First, when a start-up switch of the battery system 1 is switched on, for example, in the case where the battery system 1 is an electric vehicle, when an ignition key is ON by a user, the host controller 4 supplied with power by a small power source (not illustrated) (the single battery cell of the battery module 2 may be used as the small power source to supply power for operations of the controller, and in this case, the battery cell functions as not only a power source for power supply to the power load 3 but also the power source for operations of the controller) causes a first anti switch control signal corresponding to all the arms to be active. The BMS 6 that receives the active first arm switch control signal causes a second aria switch control signal corresponding to all the arms to be active in order to cause the arm switches Sα and Sβ to be “closed” from being “open”. The arm switches Sα and Sβ that receive the active second arm switch control signal are operated to be “closed” from being “open”. Accordingly, the battery pack of each of the arms of the battery module 2 and the power load 3 are electrically connected. Therefore, the battery system 1 is started up and is operable, for example, in the case where the battery system 1 is an electric vehicle, the electric vehicle can travel.

In addition, when the start-up switch is switched off, for example, when the ignition key is OFF by the user, the host controller 4 causes the first arm switch control signal corresponding to all the arms to be inactive. Therefore, the BMS 6 that receives the inactive first arm switch control signal causes the second arm switch control signal corresponding to all the arms to be inactive in order to cause the arm switches Sα and Sβ to be “open” from being “closed”. The arm switches Sα and Sβ that receive the inactive second arm switch control signal are operated to be “open” from being “closed”. Accordingly, the battery pack of each of the arms of the battery module 2 and the power load 3 are electrically disconnected.

When the battery system 1 is started up, in order to align the cell voltages of the battery cells CEa to CEh that vary when the battery system 1 is previously used in the predetermined range, the BMS 6 appropriately opens and closes the switches S of the cell balancing circuits Ba to Bh disposed to correspond to the respective battery cells CEa to CEh. At this time, as described above, although the battery pack of the battery module 2 and the power load 3 are electrically connected, until the cell voltages of the battery cells CEa to CEh are aligned in the predetermined range, that is, until cell balancing is completed, the operation of the power load 3 is prohibited by the host controller 4, for example, in the case where the battery system 1 is an electric vehicle, the power load 3 is in a state without current substantially flowing thereto by prohibiting pressing of the accelerator pedal and the like.

Specifically, cell balancing is performed as follows. First, based on the measurement information regarding the cell voltage values of the voltage sensors Va to Vh input into the BMS 6, the BMS 6 specifies the lowest voltage value (hereinafter, referred to as a minimum voltage value VIII) and the battery cells having the minimum voltage value Vm among all the battery cells CEa to CEh. The minimum voltage value Vin is the electromotive voltage V0 of the battery cell having the voltage value.

In addition, except for the battery cell specified to have the minimum voltage value Vin, the BMS 6 causes cell balancing circuit control signals directed to the cell balancing circuits B corresponding to the other battery cells to be active, and thus the switch S of each of the cell balancing circuits B which receives the cell balancing circuit control signal is operated to be “closed” from being “open”. Accordingly, the other battery cells are discharged, and the cell voltage values of the other battery cells become close to the minimum voltage value Vin. While the BMS 6 keeps monitoring the cell voltages value of the other battery cells by using the measurement value from each of the voltage sensors V.

When the respective cell voltage values of the other battery cells become values which are substantially determined as the same value as the minimum voltage value Vm, that is, a value in ±ΔV from the minimum voltage value Vim, the BMS 6 causes the cell balancing circuit control signals directed to each of the cell balancing circuits B corresponding to the other battery cells to be inactive, so that the switches S of the cell balancing circuits B are operated to be “open” from being “closed” and discharging is stopped. Accordingly, the electromotive voltages V0a to V0h of all the battery cells CEa to CEh are set to be substantially the same voltage value as the minimum voltage value Vm.

In addition, at this time, in a case where the connection looseness is already generated and the value of the contact resistance R1 or the contact resistance R2 is high, a high voltage drop occurs during discharging due to the contact resistance R1 or the contact resistance R2. Therefore, there may be cases where the measurement information regarding the cell voltage value of the voltage sensor V when the switch S of the corresponding cell balancing circuit is “closed” and the measurement information regarding the cell voltage value of the voltage sensor V when the switch S is “open” are significantly different from each other.

Accordingly, it is preferable that, before the measurement information has from the minimum voltage value Vin, the BMS 6 first cause the switch S of the corresponding cell balancing circuit B to be “open” from being “closed”, check the value of the electromotive voltage V0 of each of the battery cells, and predict the degree of difference described above so that the BMS 6 individually, independently, intermittently, and appropriately opens and closes the switches S of the cell balancing circuits B to cause the electromotive voltages V0a to V0h of all the battery cells CEa to CEh to have substantially the same voltage value as the minimum voltage value Vin.

When the electromotive voltages V0a to V0h of all the battery cells CEa to CEh have substantially the same voltage value as the minimum voltage value Vm under the control of each of the cell balancing circuits B by the BMS 6 described above, for example, current supply to the power load 3 is allowed by the host controller 4, and for example, in the case where the battery system 1 is an electric vehicle, pressing of the accelerator pedal by a user and the like are allowed, thereby enabling the battery system 1 to be substantially operated (current supply to the power load 3).

However, only for a short time to perform the “connection looseness determination”, the host controller 4 controls the amount of current supplied to the power load 3 to be a predetermined current value (hereinafter, referred to as a determination current value) regardless of a user's intention. For example, in the case where the battery system 1 is an electric vehicle, the host controller 4 performs control to flow a current of 100 A to each arm as the determination current value regardless of the amount of the accelerator pedal pressed by the user (here, the user is pressing the accelerator pedal). In addition, an amount of current equal to the constant determination current value may be caused to flow to each of the arms, and thus the corresponding value can be set to any value. However, in the case where the battery system 1 is an electric vehicle, the value of the determination current value is set to a value that does not substantially contribute to the movement of the electric vehicle.

Therefore, current is supplied from the battery pack of the battery module 2 to the power load 3, and at this time, current having the same current value flows to the battery cells which constitute a certain arm and are connected in series.

When the current having the same current value flows through the battery cells of the same arm, the electromotive voltages of the battery cells in the arm can be aligned to be substantially the same voltage value as the minimum voltage value Vm as described above. In addition, considering that the values of the contact resistance R1 and R2 corresponding to each of the battery cells are substantially the same as each other without connection looseness, the measurement values of the voltage sensors V disposed to correspond to the battery cells will be substantially the same. That is, the measurement values are in a range of Vm±ΔV.

However, in a case where connection looseness is present, a high voltage drop is generated by the contact resistance R1 or the contact resistance R2, and thus a voltage value Verr which is the measurement value deviating from the range of Vm+ΔV.

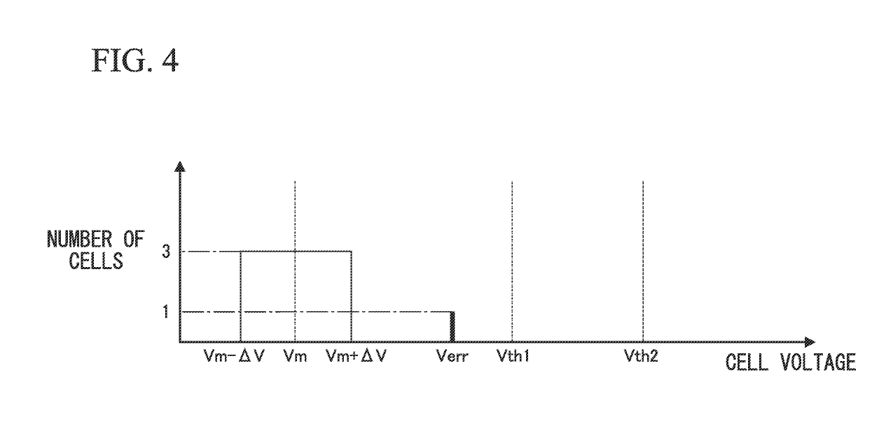

In FIG. 1, in the single arm, for example, since the four battery cells CEa to CEd are connected in series in the first arm, the relationship between the measurement err of the voltage sensor V of the single battery cell and the measurement values of the voltage sensors V of the other three battery cells is illustrated in FIG. 4.

Therefore, the host controller 4 that receives the associated information from the BMS 6 easily and exactly determines and specifies the battery cell (referred to as battery cell having connection looseness) having a voltage value Yen that deviates from a voltage value range of Vm±ΔV which is substantially the same as the minimum voltage value Vm immediately after operating the battery system 1.

Next, in a case where the connection state in the battery cell having connection looseness does not have a particular influence on the use of the battery system 1, that is, in a case where the voltage value Verr is a voltage value of less than or equal to a threshold Vth1 according to the associated information transmitted to the host controller 4 from the BMS 6 (a case of Verr≦Vth1), the host controller 4 performs the connection looseness determination that the associated information legal ding the battery cell having connection looseness and the other battery cells is not an abnormal value. Therefore, the host controller 4 does not attract a user's attention in any way. Accordingly, the host controller 4 stops control to cause the current having the determination current value to flow to each of the anus, and allows driving and operations according to the user's intention, so that the user can normally drive and operate the battery system 1.

On the other hand, in a case where there is a high risk that the busbar 10 which is the connection to the battery cells can be removed any time but the busbar is not removed yet, that is, in a case where the voltage value Verr is a voltage value of greater than or equal to a threshold Vth2 according, to the associated information transmitted to the host controller 4 from the BMS 6 (a case of Vth2≦Verr), the host controller 4 determines that the associated information regarding the battery cell having connection looseness is an abnormal value. Therefore, the host controller 4 turns on the abnormality lamp built in the display device 5 or the like, and sounds alarm by operating the acoustic device such as a buzzer built in the display device 5 to stimulate the senses of sight and hearing with light and sound and attract user's attention.

In addition, at this time, the host controller 4 stops control to cause the current having the determination current value to flow to each of the arms, and causes the first arm switch control signal corresponding to not only the arm including the battery cell having connection looseness but also all the arms to be inactive. The BMS 6 that receives the inactive first arm switch control signal causes the second arm switch control signal of the corresponding arms to be inactive in order to cause the arm switches Sα and Sβ to be “open” from being “closed”. The arm switches Sa and Sp that receive the inactive second arm switch control signal are operated to be “open” from being “closed”. Accordingly, not only the arm including the battery cell having the risk described above but also the battery pack of all the arms and the power load 3 are electrically disconnected immediately after the battery system 1 starts operating, and current supply to the power load 3 from the battery pack is stopped.

Accordingly, for example, in the case where the battery system 1 is an electric vehicle, the electric vehicle is abruptly decelerated and stopped immediately after the accelerator pedal is pressed. Therefore, before the car leaves from a garage to a public road, as well as the attraction of attention by the display device 5 and the like, the user can feel the abnormality of the battery system. Accordingly, safety of the battery system 1 can be increased, and the user can be further strongly pushed to repair the battery system 1.

Moreover, in a case of Vth1≦Verr<Vth2, although the risk that the busbar 10 which is the connection can be removed any time is not high, a risk that the connection can be removed during the operation of the battery system cannot be denied. Therefore, repair or the like of the battery system also needs to be performed urgently. In addition, when the operation of the battery system 1 continues for a long term in this state, heat is generated by the connections and the like due to the contact resistance R1 or the contact resistance R2 which is at a high level. Therefore, there is concern of the constituent components of the battery system 1 being fired.

Here, according to the associated information transmitted to the host controller 4 from the BMS 6, the host controller 4 determines the associated information regarding the battery cell having connection looseness to be not an abnormal value but an alarming value. Therefore, the host controller 4 turns on an alarming lamp (the abnormality lamp may be used in common) built in the display device 5 and the like, and sounds alarm by operating the acoustic device such as a buzzer built in the display device 5 to stimulate the senses of sight and hearing with light and sound and attract a user's attention.

In addition, at this time, the host controller 4 stops control to cause the current having the determination current value to flow to each of the arms, and based on the associated information regarding each of the temperature sensors T, limits the amount of current supplied to the power load 3 to be smaller than a predetermined current value regardless of a user's intention so that the temperature of the battery cell is in a predetermined range (for example, 60° C. or less). For example, in the case where the battery system 1 is an electric vehicle, the host controller 4 performs control to limit the amount of the accelerator pedal pressed by the user such that pressing to a degree of a predetermined pressing amount or higher cannot be made.

Therefore, in this case, since at least all the arms are electrically connected to the power load 3, the user can operate the battery system 1 with a certain degree of freedom while previously recognizing the need to repair parts of the battery cell urgently.

However, in the above description, (Vm+ΔV)<Vth1<Vth2.

Specific numerical values are described as an example. For example, when the determination current value as described above is set to 100 A, a rated electromotive voltage V0 is set to 3.7 V the contact resistances R1 and R2 in a case of a normal electrical connection are each set to 0.2 nip, and the internal resistance RU is set to 0.8 mΩ, a case where any one of the contact resistances R1 and R2 of the battery cell is increased 10 times due to connection looseness occurred can be set to the threshold Vth1, and a case of being increased 20 times can be set to the threshold Vth2. At this time, Vth1=3.7 V+(100 A×(0.8 mΩ+0.2 mΩ+2 mΩ))=4.0 V and Vth2=3.7 V+(100 A×(0.8 mΩ+0.2 mΩ+4 mΩ))=4.2 V.

In addition, for example, ΔV=0.05 V can be set.

The present invention is not limited to the above-described embodiments, and various modifications can be made without departing from the gist of the present invention. For example, in the above-described embodiments, the BMS 6 of the battery module 2 and the host controller 4 are separately described, but may also be implemented as a single controller to perform control.

In addition, the arrangements of the male screw and the female screw in each of the configurations illustrated in FIG. 2 may be reversed.

Moreover, the busbar is used as the connection which is the power supply line that connects the battery cells, but the present invention is not limited thereto. In a configuration in which the contact resistance of the power supply line and the electrode terminal is included in the electrical path on which the cell voltage of the battery cell is measured, flexural line-like wires may be employed instead of the plate-like busbars which are less likely to be flexural.

Cell balancing is described to be performed at the time of starting up the battery system. However, in a case where variations in voltage of the battery cells do not substantially occur from the time of ending of the previous operation to the time of starting up of the subsequent operation (the time of starting the operation), cell balancing may be performed at the time of ending of the previous operation. In this configuration, the connection looseness determination can be performed more rapidly.

### INDUSTRIAL APPLICABILITY

The present invention relates to the battery system capable of minutely determining the connection state between the battery cells constituting the battery pack with a simple configuration. According to the present invention, in a case where a physical connection is loosened despite the connections being not removed from the battery cells, this situation can be detected without the use of a special sensor.

### REFERENCE SIGNS LIST

1 battery system
2 battery module
3 power load
4 host controller
5 display device
6 BMS
7 positive electrode terminal (7a: female screw)
8 negative electrode terminal (8a: female screw)
9 insulating resin
10 busbar (10a: flat plate portion, 10b: protruding portion, 10c: concave portion)
11 through-hole
12 circuit board threaded hole
13 circuit board
14 through-hole
15 screw (15a: busbar screw, 15b: circuit board screw)

1. A battery system comprising:
a first battery cell including a first positive electrode terminal and a first negative electrode terminal;
a second battery cell including a second positive electrode terminal and a second negative electrode terminal;
a power load which is disposed between the first positive electrode terminal and the second negative electrode terminal and is supplied with current from the first battery cell and the second battery cell;
a connection which electrically connects the first negative electrode terminal and the second positive electrode terminal;
a first voltage sensor for measuring a cell voltage of the rust battery cell via the connection;
a second voltage sensor for measuring a cell voltage of the second battery cell via the connection;
a cell balancing circuit which enables electromotive voltages of the first battery cell to be substantially equal to that of the second battery cell; and
a controller which supplies the current to the power load while controlling the electromotive voltages of the first battery cell to be substantially equal to that of the second battery cell by using the first and the second voltage sensor, and the cell balancing circuit, thereby determining looseness of the connection.

2. The battery system according to claim 1,
wherein, in a case where the cell voltage measured by the first voltage sensor or the second voltage sensor becomes greater than a first threshold, the controller stops supplying the current to the power load.

3. The battery system according to claim 2,
wherein, in a case where the cell voltage measured by the first voltage sensor or the second voltage sensor is smaller than the first threshold and is greater than a second threshold, the controller limits the current supplied to the power load.

4. The battery system according to claim 3,
wherein the connection is a busbar including a flat plate portion and two protruding portions which are connected to the flat plate portion and are disposed with the flat plate portion interposed therebetween,
the first negative electrode terminal and the second positive electrode terminal are connected to the flat plate portion,
the first voltage sensor measures the cell voltage of the first battery cell via the one protruding portion between the two protruding portions, and
the second voltage sensor measures the cell voltage of the second battery cell via the other protruding portion between the two protruding portions.

5. A battery system comprising:
a first battery cell including a first positive electrode terminal and a first negative electrode terminal;
a second battery cell including a second positive electrode terminal and a second negative electrode terminal;
a third battery cell including a third positive electrode terminal and a third negative electrode terminal;
a first connection which electrically connects the first negative electrode terminal and the second positive electrode terminal;
a second connection which electrically connects the second negative electrode terminal and the third positive electrode terminal;
a power load which is disposed between the first positive electrode terminal and the third negative electrode terminal and is supplied with current from the first, second and third battery cells;
a first voltage sensor for measuring a cell voltage of the first battery cell via the first connection;
a second voltage sensor for measuring a cell voltage of the second battery cell via the first connection and the second connection;
a third voltage sensor for measuring a cell voltage of the third battery cell via the second connection;
a cell balancing circuit which enables electromotive voltages of the first to third battery cells to be substantially equal; and
a controller which supplies the current to the power load while controlling the electromotive voltages of the first to third battery cells to be substantially equal by using the first to third voltage sensors, and the cell balancing circuit, thereby determining looseness of the connection.

6. The battery system according to claim 5, further comprising:
a circuit board provided with the second voltage sensor,
wherein the first connection is a busbar including a first flat plate portion and a first protruding portion connected to the first flat plate portion integrally,
the second connection is a busbar including a second flat plate portion and a second protruding portion connected to the second flat plate portion integrally,
the first negative electrode terminal and the second positive electrode terminal are connected to the first flat plate portion,
the second negative electrode terminal and the third positive electrode terminal are connected to the second flat plate portion, and
the second voltage sensor measures the cell voltage of the second battery cell when the circuit board is connected to the first protruding portion and the second protruding portion.
